(19) United States
(12) Patent Application Publication
(10) Pub. No.: US 2025/0112097 A1
(43) Pub. Date: Apr. 3, 2025

(54) SEMICONDUCTOR WAFER INCLUDING A TEST STRUCTURE

(71) Applicant: Infineon Technologies Austria AG, Villach (AT)

(72) Inventors: Nicole Schulze-Ollmert, Villach (AT); Jürgen Bostjancic, Ludmannsdorf (AT); Christian Fachmann, Villach (AT); Ingo Muri, Villach (AT); Holger Busch, GroBréhrsdorf (DE)

(21) Appl. No.: 18/897,023

(22) Filed: Sep. 26, 2024

(30) Foreign Application Priority Data
Sep. 29, 2023 (DE) 102023126767.1

(51) Int. Cl. H01L 21/66

(52) U.S. Cl. CPC H01L 22/32

(57) ABSTRACT

Disclosed is a semiconductor wafer including a test structure. The test structure includes a pad arrangement arranged above a kerf region of a semiconductor wafer. The pad arrangement includes: contact pads arranged in series in a first direction; and two alignment pads arranged in series with the contact pads in the first direction such that the contact pads are arranged between the two alignment pads. Each of the contact pads comprises a metal. Each of the alignment pads is different from each of the contact pads and is configured to be irreversibly deformed when coming into contact with a probe needle.

### TECHNICAL FIELD

This disclosure relates in general to a semiconductor wafer including a test structure.

### BACKGROUND

Forming semiconductor devices, such as transistor devices, diodes, or the like, may include forming a plurality of semiconductor devices using the same manufacturing processes on a wafer. The wafer includes a plurality of semiconductor bodies, which are regions of the wafer that includes active device regions of the semiconductor devices, and kerf regions arranged between the semiconductor bodies. At the end of the manufacturing process, the wafer is separated in order to obtain a plurality of individual semiconductor bodies (dies, chips), which may finally be packaged.

Forming a semiconductor device may include a plurality of process sequences. Such process sequences may include implantation processes in which dopant atoms are implanted into the semiconductor bodies included in the wafer. In order to be able to monitor the quality of the manufacturing processes, test structures may be formed in the kerf regions. These test structures, which may also be referred to as PCM (Process Control Monitoring) structures are formed by the same manufacturing processes used for forming the semiconductor devices. The quality of the manufacturing processes can be evaluated by measuring electric characteristics of the test structures, for example. In order to be able to measure electric characteristics of the test structures one or more test pads connected to the test structures are formed above the kerf region.

Measuring the electric characteristics of the test structures may include bringing probe needles of a test equipment in contact with the test structure electrodes.

The test structure electrodes are very small and may have a size of only several thousand square micrometers. During the evaluation process it is essential that the probe needles come into contact with the test pads correctly. Conventional test pads include an electrically conducting material that is less hard than electrically conducting material of the probe needles, so that the probe needles leave an imprint on the test pads. After the measuring process, positions of the imprints on the test pads can be evaluated by optical inspection in order to evaluate whether the probe needles have been aligned correctly with respect to the test pads and have contacted the test pads.

This type of optical inspection is not possible when the test pads include a material, such as tungsten (W), that is as hard as the material of the probe needles. In this case, the probe needles hardly leave an imprint on the test pads.

There is a need for an improved test structure.

### SUMMARY

One example relates to a test structure. The test structure includes a pad arrangement arranged above a kerf region of a semiconductor wafer. The pad arrangement includes contact pads arranged in series in a first direction, two alignment pads arranged in series with the contact pads in the first direction such that the contact pads are arranged between the two alignment pads. Each contact pad includes a metal, and each of the alignment pads is different from each of the contact pads and is configured to be irreversibly deformed when coming into contact with a probe needle.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a top view of a pad arrangement of a test structure including several contact pads arranged in series and between two alignment pads;

FIG. 2 schematically illustrates a top view of a wafer including a plurality of semiconductor bodies and kerf regions arranged between the semiconductor bodies;

FIGS. 3A-3B each illustrate a detailed view of one portion of the kerf region;

FIGS. 4A-4B illustrate a vertical cross-sectional view and a top view of one alignment pad according to one example;

FIG. 5 illustrates a vertical cross-sectional view of one contact pad according to one example;

FIG. 6 schematically illustrates probe needles of a probe arrangement;

FIGS. 7A-7C illustrate different scenarios that may occur when bringing the probe needles in contact with the contact and alignment pads;

FIGS. 8A-8B shows top views of an alignment pad before and after bringing a probe needle in contact with the alignment pad;

FIGS. 9-10 illustrate more detailed views of an alignment pad according to different examples;

FIG. 11 shows a more detailed view of a contact pad according to one example;

FIG. 12 shows a vertical cross-sectional view of one portion of a semiconductor body in which active regions of a transistor device are integrated;

FIG. 13 shows a top view of a transistor device according to one example;

FIG. 14 illustrates a vertical cross-sectional view of one portion of the kerf region that includes a test structure according to one example;

FIG. 15 illustrates a vertical cross-sectional view of one portion of the test structure illustrated in FIG. 14;

FIGS. 16A-16B illustrates a modification of the test structure according to FIGS. 14 and 15;

FIG. 17 illustrates a further modification of the test structure according to FIGS. 14 and 15; and

FIG. 18 illustrates a modification of the test structure according to FIG. 17.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

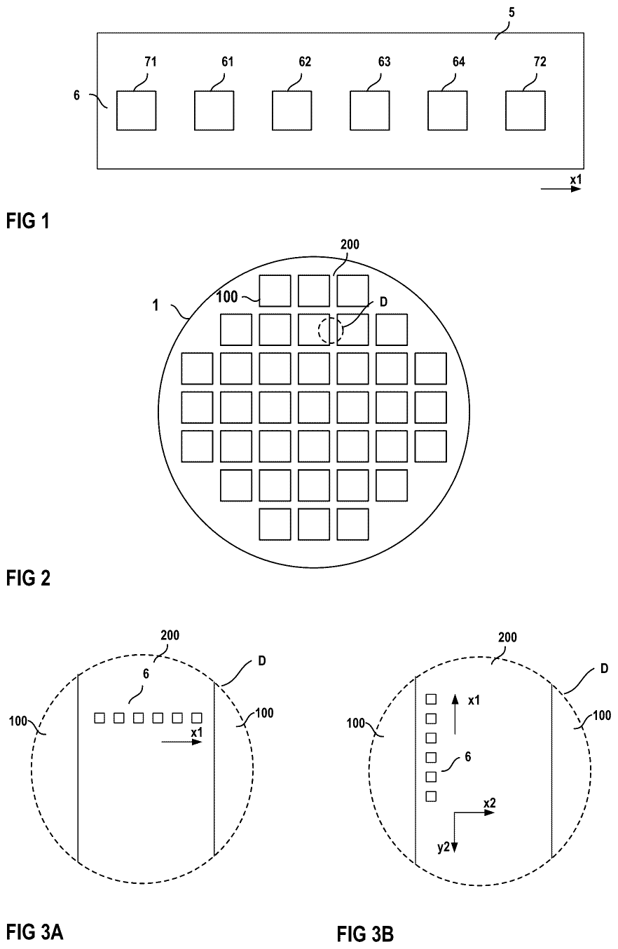

FIG. 1 schematically illustrates a top view of a pad arrangement 6 of a test structure. The pad arrangement 6 includes a plurality of contact pads 61-64 that are arranged in series and spaced apart from each other in a first lateral direction x1. The pad arrangement 6 further includes 2 alignment pads 71, 72. The alignment pads 71, 72 are arranged in series with the contact pads 61-64 in the first lateral direction x1 such that the contact pads 61-64 are arranged between the two alignment pads 71, 72. Each of the two alignment pads 71, 72 is spaced apart from the contact pads 61-64.

A size of the individual pads 71, 72, 61-64 is several thousand square micrometers, for example. According to one example, the pads 71, 72, 61-64 have the shape of rectangles, in particular, squares, with an edge length of between 50 micrometers and 120 micrometers.

With regard to the first lateral direction x1 it should be noted that, unless stated otherwise, “first lateral direction” includes both the direction as indicated by the arrow labelled with x1 in FIG. 1 and the opposite direction.

Each of the contact pads 61-64 includes a metal. The metal is tungsten (W) or titanium (Ti), for example.

The alignment pads 71, 72 are different from the contact pads 61-64. That is, the alignment pads 71, 72 are implemented differently from the contact pads 61-64. Each of the alignment pads 71, 72 is configured to be irreversibly deformed when coming into contact with a probe needle. This is explained in detail herein further below.

The pad arrangement illustrated in FIG. 1 is arranged above a kerf region 200 of a semiconductor wafer, for example.

FIG. 2 schematically illustrates a top view of a semiconductor wafer 1. The semiconductor wafer 1 includes a plurality of semiconductor bodies 100 and kerf regions 200 arranged between the semiconductor bodies 100 and separating the semiconductor bodies 100 from one another. The kerf regions 200 may also be referred to as kerf portions 200 of the wafer 1.

The wafer is a contiguous monocrystalline semiconductor wafer, for example, which is separated at the end of the manufacturing process to obtain a plurality of individual semiconductor bodies (dies) 100. The monocrystalline semiconductor material is a conventional monocrystalline semiconductor material such as, for example silicon (Si), silicon carbide (SiC), gallium arsenide (GaAs), gallium nitride (GaN), or the like. Due to the wafer being a monocrystalline wafer, there is no visible border between the semiconductor bodies 100 and the kerf regions 200 on the wafer 1.

During the manufacturing process, device regions of semiconductor devices are formed in the semiconductor bodies 100. The manufacturing process may include implantation processes, wherein in each implantation process dopant atoms are implanted into predefined regions of the semiconductor bodies 100. The manufacturing process may further include forming insulating layers and electrode layers above the wafer 1 before separating the wafer.

The number of semiconductor bodies 100 in the wafer 1 is dependent on the size of the individual semiconductor bodies 100 and the size of the wafer 1. The overall number is between several 10 and several 100, for example. The wafer 1 is separated by sawing along the kerf regions 200, for example. In this way, at least portions of the kerf regions 200 are removed.

Referring to the above, the pad arrangement 6 may be arranged above the kerf region 200 of the wafer. More specifically, the pad arrangement 6 may be arranged in or above an insulating layer 5 formed on top of the semiconductor bodies 100 and the kerf region 200 of the wafer. The insulating layer 5, however, is not illustrated in FIG. 2.

FIGS. 3A and 3B each illustrate an enlarged view of a portion D of the wafer 1, wherein the portion D illustrated in FIGS. 3A and 3B includes a portion of the kerf region 202 and portions of two semiconductor bodies 100 arranged adjacent to the illustrated kerf region 200 on opposite sides. FIGS. 3A and 3B illustrate two different examples for arranging the gate pad arrangement above the kerf region 200.

According to one example illustrated in FIG. 3A, the lateral direction x1 in which the contact and alignment pads are arranged in series corresponds to a direction in which the two semiconductor bodies 100 adjoining the kerf region 200 are spaced apart from each other. In this case, the lateral direction x1 may be essentially perpendicular to a line along which the wafer 1 is finally separated.

According to another example illustrated in FIG. 3B, the lateral direction x1 in which the contact and alignment pads are arranged in series corresponds to a direction that is essentially perpendicular to a direction in which the two semiconductor bodies 100 adjoining the kerf region 200 are spaced apart from each other. In this case, the lateral direction x1 may be essentially parallel to a line along which the wafer 1 is finally separated.

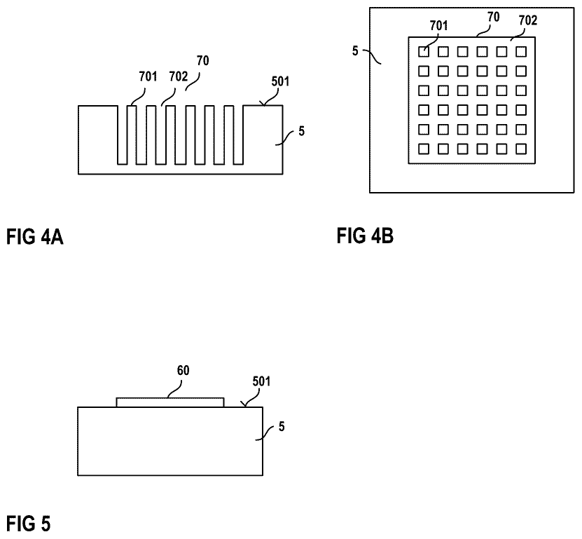

FIGS. 4A and 4B illustrate an alignment pad 70 according to one example. Reference number 70 in FIGS. 4A and 4B represents an arbitrarily one of the two alignment pads 71, 72 explained before. FIG. 4A shows a vertical cross-sectional view of the alignment pad 70, and FIG. 4B shows a top view. More specifically, FIG. 4A shows a vertical cross-sectional view of one portion of an insulating layer 5 in which the alignment pad 70 is formed.

Referring to FIGS. 4A and 4B, the alignment pad 70 includes a plurality of elements 701 that are spaced apart from each other and separated from each other by a trench 702 and that are configured to break off when coming into contact with a probe needle. A cross-sectional area of each of these elements 701 is less than 1 square micrometer, for example. The trench 702 extends from the first surface 501 of the insulating layer 5 into the insulating layer 5 and defines the elements 701. The insulating layer 5 is an oxide layer, for example. In FIGS. 4A and 4B only elements 701 are schematically illustrated. The overall number of needles of one alignment pad 70 may range from between several hundred to several thousand.

Referring to FIG. 4, the individual elements may each have the shape of a needle. The elements 701 are therefore also referred to as needles in the following. The shape of the individual elements, however, is not restricted to a needle shape. Instead, the individual elements 701 may be implemented with any other shape that enables the individual elements 701 to break off when coming into contact with a probe needle. The individual elements 701 may have the same shape. However, it is also possible to implement one alignment pad with elements 701 of different shapes.

FIG. 5 schematically illustrates a vertical cross-sectional view of one contact pad 60 according to one example. Reference number 60 in FIG. 5 represents an arbitrarily one of the contact pads 61-64 explained before. In the example illustrated in FIG. 5, the contact pad 60 is formed on top of the surface 501 of the insulating layer 5. FIG. 5 shows a vertical cross-sectional view of the insulating layer 5 and the contact pad 60. Referring to the above, the contact pad 60 includes a metal such as tungsten or titanium.

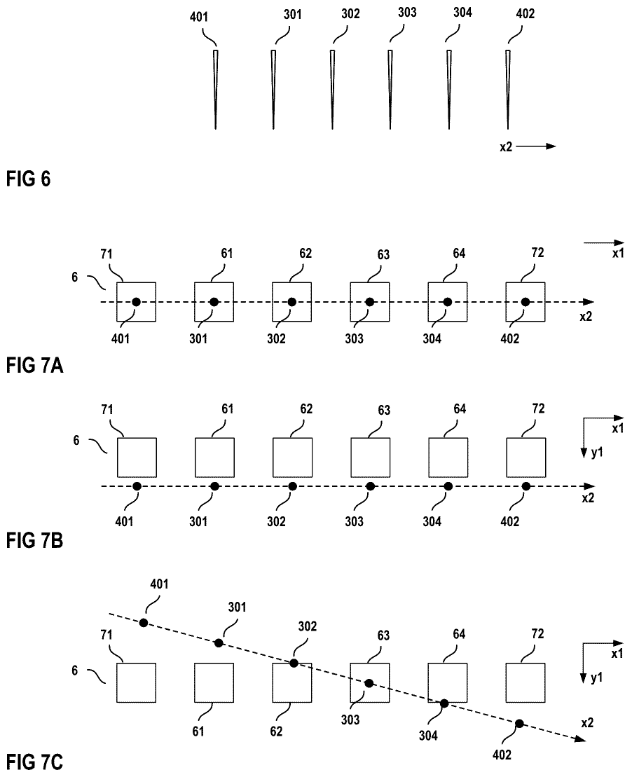

According to one example, the pad arrangement 6 serves to make contact between a doped test region arranged in the kerf region 200 and a test equipment. The test equipment may include a plurality of probe needles. An example of a probe needle arrangement that is configured to be brought in contact with a pad arrangement 6 of the type explained before, is illustrated in FIG. 6. In this example, the probe needle arrangement includes a plurality of needles that are arranged in series in a second lateral direction x2. The needles may include contact needles 301-304 and alignment needles 401, 402.

The alignment needles 401, 402 are arranged in series with the contact needles 301-304 such that the contact needles 301-304 are arranged between the alignment needles 401, 402. The contact needles 301-304 on one side and the alignment needles 401-402 on the other side may be implemented in the same way. Contact needles 301-304 and alignment needles 401, 402, however, have different functionalities.

Each of the contact needles 301-304 is configured to make electrical contact with a respective one of the contact pads 61-64 in order to drive a current into the respective contact pad 61-64 or to measure a voltage between two contact pads 61-64, for example. Each of the alignment needles 401-402 is configured to make physical contact with a respective one of the alignment pads 71, 72 and to irreversibly deform the respective alignment pad 71, 72 when being brought in contact with the respective one of the alignment pads 71, 72.

In a measurement process, the alignment needles 401, 402 are brought in contact with the alignment pads 71, 72 at the same time the contact needles 301-304 are brought in contact with the contact pads 61-64. After the measurement process, by optical inspection of the alignment pads 71, 72, information can be obtained of how good the needle arrangement was aligned to the pad arrangement during the measurement process.

Different scenarios of aligning the probe needle arrangement relative to the pad arrangement 6 are illustrated in FIGS. 7A-7C. Each of these figures schematically illustrates a top view of the alignment pads 71, 72 and the contact pads 61-64 of the pad arrangement 6 and a to view of the alignment needles 401, 402 and the contact needles 301-304 during one measurement process.

FIG. 7A illustrates an example, in which the probe needle arrangement is perfectly aligned relative to the pad arrangement 6. That is, each of the alignment needles 401, 402 is brought in contact with the respective alignment pad 71, 72 essentially in the center of the respective alignment pad 71, 72, and each of the contact needles 301-304 is brought in contact with the respective contact pad 61-64 essentially in the center of the respective contact pad 61-64.

FIG. 7B illustrates a scenario in which the direction x2 in which the needles 401, 402, 301-304 are arranged in series is essentially parallel to the first direction x1, but the probe needle arrangement is offset relative to the pad arrangement 6 in a lateral direction y1 that is essentially perpendicular to the first direction x1. FIG. 7B illustrates a worst-case scenario, in which each of the needles 401, 402, 301-304 does not make contact to the respective pad 71, 72, 61-64.

FIG. 7C illustrates a scenario in which the probe needle arrangement is tilted relative to the pad arrangement 6 such that the direction x2 in which the needles 401, 402 are arranged in series is not parallel to the first direction x1. In this scenario, some of the probe needles (302, 303, 304) may make contact with the respective pad, while others of the probe needles (401, 301, 402) may not make contact with the respective pad.

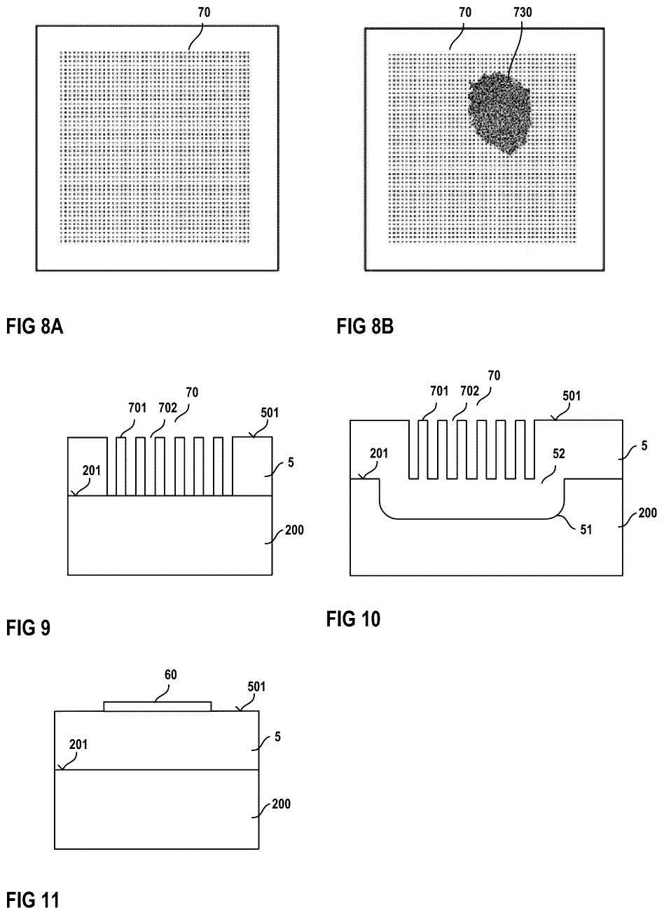

FIG. 8A shows a top view of one alignment pad 70 before the measurement process, that is, before the respective alignment needle has been brought in physical contact with the alignment pad 70. FIG. 8B shows a top view of the alignment pad 70 after the measurement process, that is, after the respective alignment needle has been brought in contact with the alignment pad. Referring to the above, the alignment needle irreversibly deforms the alignment pad. That is the alignment needle breaks off several of the needles leaving an imprint 730 that includes broken needles.

Based on the position of the imprint 730 on each of the alignment pads 71, 72 the alignment of the probe needle arrangement relative to the pad arrangement 6 during the measurement process can be evaluated. Based on this evaluation, the needle arrangement can be suitably readjusted, if required.

According to one example, the contact needles 301-304 include a metal that is as hard as the metal of the contact pads 61-64, so that the contact needles 301-304 do not leave significant marks on the contact pads 61-64. Thus, the alignment of the needle arrangement relative to the pad arrangement 6 can be evaluated based on the alignment pad 71, 72 that are irreversibly deformed by the alignment needles 401, 402. It should be noted that the alignment needles 401, 402 not necessarily include the same material as the contact needles 301-304 and that the alignment needles 401, 402 are not necessarily electrically conducting.

FIG. 9 illustrates a vertical cross-sectional view of one alignment pad 70 according to one example in greater detail. In the example illustrated in FIG. 9, the trenches 702 that define the needles 701 in the insulating layer 5 extend through the insulating layer 5 down to a surface 201 of the wafer in the kerf region 200. In some cases the manufacturing process of the semiconductor devices that are formed based on the wafer may include processes that are performed after forming the alignment pad 70 and that may involve substances that etch semiconductor material of the wafer 1 relative to the material of the insulating layer 5. In this case, portions of the wafer below the needles 701 may be removed, so that some of the needles may fall over already during the manufacturing process. This could be avoided by providing a thicker insulating layer 5 on top of the surface 201 such that the trenches 702 to do not extend entirely through the insulating layer 5 to the wafer surface 21. In some cases, however, such thick insulating layers 5 are not desirable.

FIG. 10 illustrates a modification of the alignment pad 70 illustrated in FIG. 9. In the example illustrated in FIG. 10, the alignment pad 70 is formed above an insulating trench 51 that extends from the surface 201 into the kerf region 200 of the wafer and that is filled with an insulating layer 52. The alignment pad 70 is formed such bottoms of the trenches 702 defining the needles 701 are spaced apart from a bottom of the insulating trench 51. The insulating layer 52 filling the insulating trench 52 may include the same material as the material of the insulating layer 5 and is an oxide, for example. In the example illustrated in FIG. 10, bottoms of the trenches 702 defining the needles 701 adjoin the insulating layer 52 filling the trench 51, so that no semiconductor regions are exposed at the bottoms of the trenches 702 defining the needles 701.

FIG. 11 schematically illustrates a vertical cross-sectional view of one contact pad 60, according to another example. In FIG. 11, the contact pad 60 is arranged above the kerf region 200 of the wafer 1.

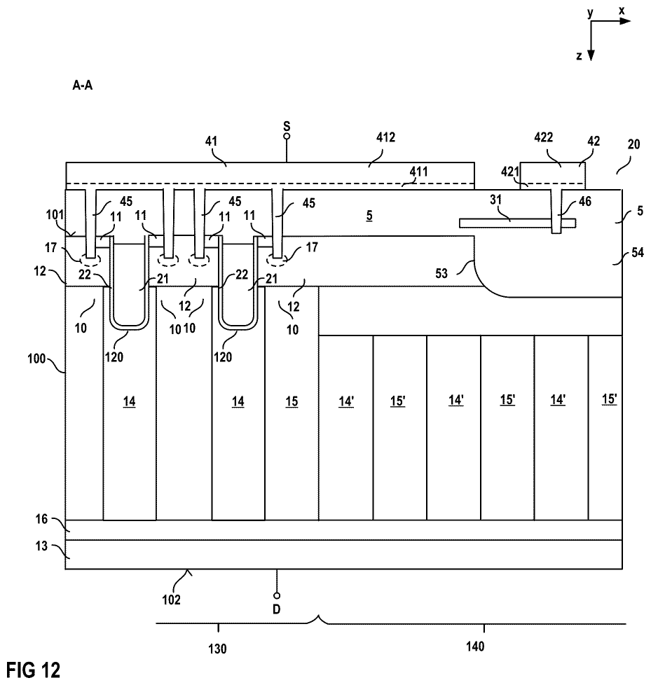

Referring to the above, various types of semiconductor devices may be implemented based on the semiconductor bodies 100 of the wafer 1. According to one example, the semiconductor devices implemented based on the semiconductor bodies 100 are transistor devices. FIG. 12 shows a vertical cross-sectional view of one portion of a semiconductor body 100 in which active regions of a transistor device are integrated.

Referring to FIG. 12, the semiconductor body 100 includes an inner region 130 in which transistor cells 10 of the transistor device are implemented, and an edge region 140 surrounding the inner region in lateral directions. In the finished transistor device, that is, after separating the wafer 1, the edge region 140 is located between sidewalls of the semiconductor body 100 and the inner region 130. The sidewalls result from separating the wafer 1 and terminate the semiconductor body 100 in lateral directions. Lateral directions are directions that are essentially parallel to first and second surfaces 101, 102 of the semiconductor body 100.

Referring to FIG. 12, each transistor cell 10 includes a source region 11 of a first doping type, a body region 12 of a second doping type complementary to the first doping type, and a gate electrode 21. The gate electrode 21 is adjacent to the body region 12, is dielectrically insulated from the body region 12 by a gate dielectric 22, and is arranged in a gate trench 120 extending from the first surface 101 of the semiconductor body 100 into the semiconductor body 100.

Referring to FIG. 12, source and body regions 11, 12 of two neighboring transistor cells 10 may be arranged in a mesa region between neighboring gate trenches 120. In this example, the body regions 12 of the two neighboring transistor cells 10 may be formed by one contiguous doped region of the second doping type. Furthermore, two (other) neighboring transistor cells may share the gate electrode 21. That is, the gate electrodes 21 of two neighboring transistor cells may be formed by one contiguous electrode arranged in one gate trench 120.

The gate electrodes 21 include an electrically conducting material. Examples of the electrically conducting material include doped polysilicon, or a metal. The gate dielectric 22 includes an oxide, for example. According to one example, the oxide is silicon oxide (SiO₂).

Referring to FIG. 12, the transistor device further includes a source electrode 41 that is arranged above the first surface 101 and is separated from the semiconductor body 100 and the gate electrodes 21 by an insulating layer. The insulating layer 5 that separates the source electrode 41 from the semiconductor body 100 may be the same insulating layer on top of which the contact pads 61-64 of the pad arrangement 6 (not illustrated in FIG. 12) are arranged above the kerf region 200 of the wafer 1. The source electrode 41 either forms a source node S or is connected to the source node S of the transistor device.

The source electrode 41 is electrically connected to the source and body regions 11, 12 of the transistor cells 10. In the example illustrated in FIG. 12, the source electrode 41 is connected to the source and body regions 11, 12 through electrically conducting vias 45 that extend from the source electrode 41 through the insulating layer 5 down to the source and body regions 11, 12.

Optionally, body contact regions 17 of the second doping type are arranged between the vias 45 and the body regions 12. The body contact regions 17 have a higher doping concentration than the remainder of the body regions 12 and serve to provide for an ohmic contact between the vias 45 and the body regions 12.

Referring to FIG. 12, the transistor device further includes a drift region 14 of the first doping type. The drift region 14 adjoins the body regions 12 of the transistor cells 10 so that PN junctions are formed between the body regions 12 of the second doping type and the drift region 14 of the first doping type. Furthermore, in a vertical direction z of the semiconductor body 100, the drift region 14 is arranged between the body regions 12 and a drain region 13 of the first doping type. The drain region 13 may adjoin a second surface 102 opposite the first surface 101. The vertical direction z is a direction that is essentially perpendicular to the first and second surface is 101, 102.

Optionally, a buffer region 16 of the first doping type and having a doping concentration that is higher than the doping concentration of the drift region 14 and lower than the doping concentration of the drain region 13 is arranged between the drift region 14 and the drain region 13.

Referring to FIG. 12 and as explained above, the gate trenches with the gate electrodes 21 may be spaced apart from each other in a first lateral direction x of the semiconductor body 100. According to one example, the gate electrodes 21 are implemented as stripe electrodes (elongated electrodes). In this example, longitudinal directions of the gate electrodes 21 correspond to a second lateral direction y perpendicular to the first lateral direction x.

According to one example, the transistor device is implemented as a superjunction transistor device. In this example, the transistor device includes a plurality of compensation regions 15 (illustrated in dashed lines) that are spaced apart from each other in a lateral direction of the semiconductor body 100. Each of the compensation regions 15 is adjacent to a respective portion of the drift region 14.

Just for the purpose of illustration, in the example illustrated in FIG. 12, the compensation regions 15 are spaced apart from each other in the first lateral direction x of the semiconductor body 100. According to another example (not illustrated) the compensation regions 15 are spaced apart from each other in the second lateral direction y of the semiconductor body 100.

The transistor device can be operated in an on-state or an off-state. In the on-state, there are conducting channels in the body regions 12 along the gate dielectrics 22 between the source regions 11 and the drift region 14. For this, the drift region 14 adjoins the gate dielectric 22 and the body region 12 of at least one of the transistor cells 10.

Furthermore, each of the optional compensation regions 15 is adjacent to at least one of the portions of the drift region 14 and is connected to the source electrode 41. In the example illustrated in FIG. 12, each of the compensation regions 15 adjoins the body region 12 of at least one transistor cell and is connected to the source electrode 41 via the respective body region 12.

The transistor device can be operated in a conventional way by applying a drive voltage (gate-source voltage) between the gate electrodes 21 and the source electrode 41. The transistor device is in the on-state (conducting state) when the drive voltage is such that conducting channels are generated in the body regions 12 along the gate dielectrics 22 between the source regions 11 and the drift region 14. The transistor device is in the off-state (blocking state) when the electrically conducting channels are interrupted.

The transistor device can be implemented as an N-type transistor device or as a P-type transistor device. An N-type transistor device, for example, is in the on-state, when the drive voltage is higher than a predefined positive threshold voltage and in the off-state, when the drive voltage is below the threshold voltage.

In an N-type transistor device, the doped regions of the first doping type are N-type regions and the doped regions of the second doping type are P-type regions. In a P-type transistor device, the doped regions of the first doping type are P-type regions and the doped regions of the second doping type are N-type regions.

The source regions 11, the body regions 12, the drift and compensation regions 14, 15, the buffer region 16, and the drain region 13 may also be referred to as (active) device regions of the transistor device.

FIG. 12 further illustrates one portion of an edge termination structure of the transistor device. The edge termination structure is arranged in and above the edge region 140 of the semiconductor body 100. According to one example, the edge termination structure includes an edge trench 53 extending from the first surface 101 into the edge region 140 of the semiconductor body 100 and filled with an electrically insulating layer 54. The edge trench 53 with the insulating layer 51 may surround the inner region 130 in lateral directions.

According to one example, insulating trench 51 below the alignment pad 70 illustrated in FIG. 10 and the insulating layer 52 filling the insulating trench 51 are formed by the same processes that form the edge trench 53 of the edge termination structure of the transistor device and the insulating layer 54 filling the edge trench 53.

Referring to FIG. 12, the edge termination structure may further include a field electrode 31 arranged above the edge trench 53 and electrically connected to a gate runner 42. The gate runner is formed above the insulating layer 42 and is connected to the field electrode 31 through an electrically conducting via 46. The field electrode 31 includes doped polysilicon, for example.

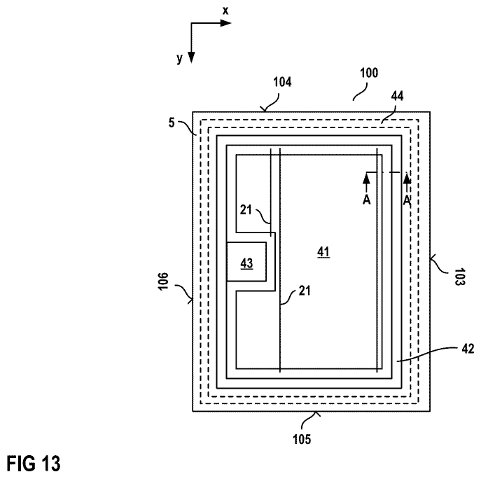

The gate runner 42 is connected to a gate pad 43 that forms a gate node of the transistor device. This is illustrated in FIG. 13 that illustrates a top view of the transistor device (after separating the wafer) according to one example. In FIG. 13, reference numbers 103-106 denote the sidewalls of the semiconductor body 100. The transistor cells are out of view in FIG. 13. Just for the purpose of illustration, elongated gate electrodes 21 arranged below the source electrode 41 of some transistor cells 21 are schematically illustrated in FIG. 13. Each of the gate electrodes 21 is connected to the gate runner 42 at at least one of its longitudinal ends. Connections between the gate electrodes 21 and the gate runner 42, however, are not illustrated in FIG. 13.

The edge termination structure may further include a drain runner 44 (illustrated in dashed lines) that is arranged above the insulating layer 5. The drain runner may be connected to the drain region 13 or the buffer region 16 through field stop regions (not illustrated) of the first doping type arranged close to the sidewalls 103-106 and extending from the drain region 13 or the buffer region 16 to the first surface 101.

The vertical cross-sectional view illustrated in FIG. 12 corresponds to a vertical cross-sectional view in a section plane A-A illustrated in FIG. 13, for example.

Drift and compensation regions may also be formed in the edge region 140, wherein reference number 14′ denotes drift regions arranged in the edge region 140, and reference number 15′ denotes compensation regions arranged in the edge region 140.

Referring to FIG. 12, each of the source electrodes 41 and the gate runner 42 (and equivalently the gate pad 43 not illustrated in FIG. 12) may include a first conducting layer 411, 421 and a second conducting layer 412, 422. According to one example, the first conducting layers 411, 421 of the source electrode 41 and the gate runner 42 are formed by the same process in which the contact pads 61-64 of the gate pad arrangement 6 are formed and, therefore, include the same material. According to one example, the first conducting layers 411, 421 also form the conducting vias 45, 46. That is, the first conducting layers 411, 421 at least partially fill via trenches in which the vias 45, 46 are formed.

The second electrically conducting layers 412, 422 may be thicker than the first electrically conducting layers 411, 412 and may include aluminum (Al), copper (Cu) or an aluminum-copper alloy, for example.

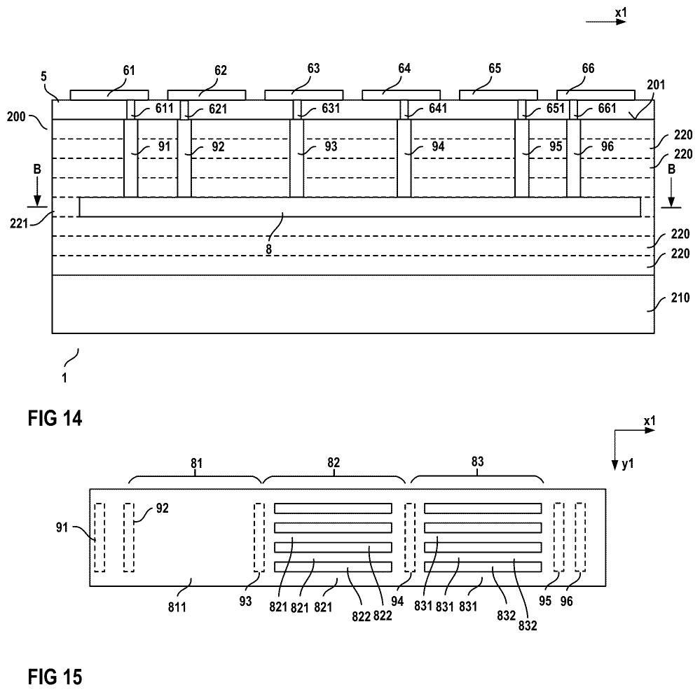

FIG. 14 illustrates one example of a test structure in greater detail. More specifically, FIG. 14 illustrates a vertical cross-sectional view of one portion of the wafer in the kerf region 200, the insulating layer 5 formed on top of the kerf region 200, and the test structure. The pad arrangement is formed on top of the insulating layer 5 and includes contact electrodes 61-66 in this example. The alignment pads are not illustrated in FIG. 14.

The wafer may include a plurality of epitaxial layers formed on top of a semiconductor substrate. In FIG. 14, reference number 210 denotes a portion of the substrate and reference numbers 220 denote portions of the epitaxial layers arranged in the edge region (edge portion) 200 of the wafer 1. In the semiconductor bodies 100, the substrate may form the respective drain region 13 explained before. In a superjunction transistor device, the drift and compensation regions 14, 15 may be formed by implanting dopant atoms into the epitaxial layers and by activating the implanted dopant atoms in one or more annealing processes.

The test structure illustrated in FIG. 1 includes a doped test region 8 in one 221 of the epitaxial layers and may be used to evaluate (monitor) the implantation and annealing process in the respective epitaxial layer 221. The doped test region 8 is formed by the same processes in which dopant atoms are implanted into the respective epitaxial layer in the semiconductor body 100 and in which the implanted dopant atoms are activated.

The doped test region 8 is connected to the contact pads 61-66 through doped contact regions 91-96 extending from the doped test region 8 to the first surface 201 of the wafer 1 in the edge region 200 and each connected to a respective contact pad 61-66 through a respective electrically conducting via 611-661 formed in the insulating layer 5. The doped contact regions 91-96 may extend through further epitaxial layers and may be formed by implanting dopant atoms into the further epitaxial layers at respective positions to form the doped contact regions 91-96.

FIG. 15 illustrates a horizontal cross-sectional view of a doped test region according to one example. That is, FIG. 15 illustrates a horizontal cross-sectional view of one portion of the epitaxial layer 221 in which the doped test region 8 is arranged. Positions of the contact regions 91-96 formed between the dopant test region 8 and the surface 201 are illustrated in dashed lines in FIG. 15.

The doped test region 8 includes at least one of three different regions, a first test region 81, a second test region 82, and a third test region 83. Just for the purpose of illustration, the doped test region 8 illustrated in FIG. 15 includes each of the first, second, and third test regions 81, 82, 83.

Referring to FIG. 15, the first test region 81 is an essentially homogeneous doped region 811 of the first doping type, which may be the same doping type as the drift region 14, 14′ in the transistor device explained before.

Referring to FIG. 15, the second test region 81 may include a plurality of elongated doped regions 821 of the first doping type. Longitudinal directions of these elongated doped regions 821 may correspond to the first direction x1 in which the contact pads 61-66 are arranged in series. Furthermore, the elongated doped regions 821 are spaced apart from each other in a direction y1 perpendicular to longitudinal directions.

Lengths of the elongated doped regions 821, which are dimensions of these regions in the first direction x1, are between 50 micrometers and 250 micrometers, for example. Widths, which are dimensions of these regions in the second direction y1, and mutual distances of the elongated doped regions 821 are in the range of between 1.5 micrometers and 5 micrometers, for example.

The epitaxial layer 221 in which the doped test region 8 is formed may have a (low) basic doping before dopant atoms are implanted. Regions 822 of the second test region arranged between the elongated doped regions 821 may have the basic doping of the epitaxial layer 221.

Referring to FIG. 15, the third test region 83 may include a plurality of elongated first doped regions 831 of the first doping type and a plurality of elongated second doped regions 832 of a second doping type complementary to the first doping type. Longitudinal directions of the first and second doped regions 831, 832 may correspond to the first direction x1. The first and second doped regions 831, 832 are arranged alternatingly in a direction y1 perpendicular to longitudinal directions of the first and second doped regions 831, 832.

Lengths of the elongated first and second doped regions 821, which are dimensions of these regions in the first direction x1, are between 50 micrometers and 250 micrometers, for example. Widths, which are dimensions of these regions in the second direction y1, are in the range of between 1.5 micrometers and 5 micrometers, for example.

In the example illustrated in FIG. 15, the first, second, and third test regions 81, 82, 83 are arranged in series in the first direction x1.

Based on electrical characteristics of the first, second, and third test regions 81, 82, 83 the implantation and annealing process can be evaluated. According to one example, resistances of the first, second, and third test regions 81, 82, 83 may be measured. Measuring the electrical resistances may include driving a current via contact pads 61, 66 and the corresponding contact regions 91, 96 through the three test regions 81, 82, 83. The contact regions 91, 96 are connected to the doped test region 8 at positions between which the first, second, and third test regions 81, 82, 83 are arranged in series.

Measuring the electrical resistance of the first test region 81 may include measuring a voltage between contact pads 62, 63 that are connected to the first test region 81 through the respective contact regions 92, 93 at positions that are spaced apart from each other in the first direction x1. Measuring the electrical resistance of the second test region 82 may include measuring a voltage between contact pads 63, 64 that are connected to the second test region 82 through the respective contact regions 93, 94 at positions that are spaced apart from each other in the first direction x1. Measuring the electrical resistance of the third test region 83 may include measuring a voltage between contact pads 64, 65 that are connected to the third test region 83 through the respective contact regions 94, 95 at positions that are spaced apart from each other in the first direction x1. The electrical resistance of the respective test region 81, 82, 83 is given by the voltage measured across the respective test region divided by a current driven through each of the test regions 81, 82, 83.

The same contact pad may be used to measure the voltage across two of the test regions 81, 82, 83. In the example illustrated in FIG. 15, for example, contact pad 63 is used for both measuring the voltage across the first test region 81 and measuring the voltage across the second test region 82. Equivalently, contact pad 64 is used for both measuring the voltage across the first test region 82 and measuring the voltage across the third test region 83.

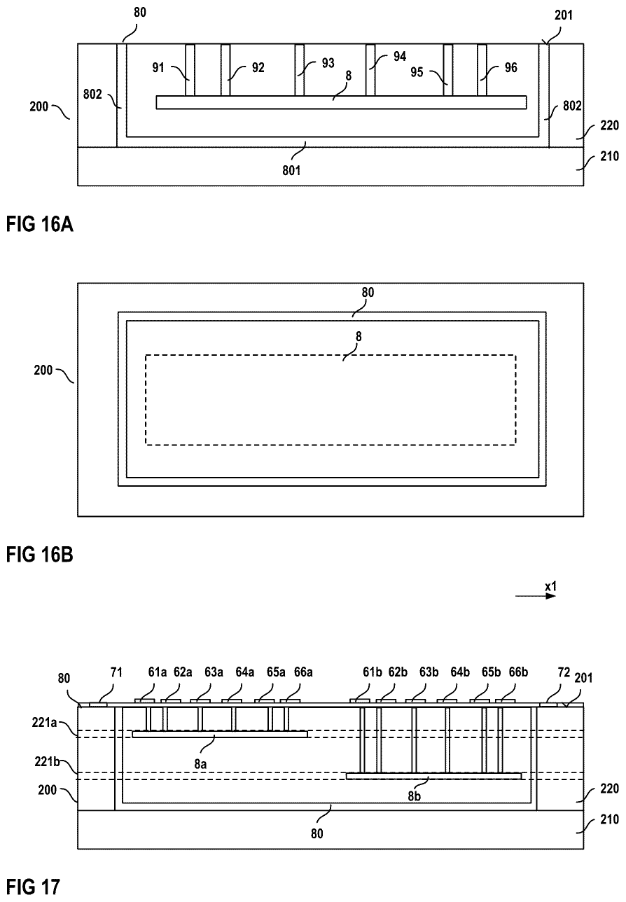

According to one example illustrated in FIGS. 16A and 16B, the doped test region 8 is surrounded by a shielding region 80 of the second doping type. FIG. 16A illustrates a vertical cross-sectional view of the edge region 200 in a section that includes a doped test region 8 of the type according to one of FIGS. 14 and 15 and the corresponding contact regions 91-96. FIG. 16B shows a top view of the edge portion 20. The insulating layer and the gate pad arrangement are not illustrated in these figures.

Referring to FIG. 16A, the shielding region includes a bottom portion 801 arranged between the doped test region 8 and the substrate 210, and sidewall portions 802 adjoining the bottom portion 801 and surrounding the doped test region 8 in lateral directions. The shielding region 80 may be formed by implanting second type dopant atoms into the epitaxial layers that are formed one above the other on the substrate 210.

FIG. 17 illustrates a test structure according to another example. In the example illustrated in FIG. 17, two doped test regions, a first doped test region 8a and a second doped test region 8b are arranged in the same shielding region 18. Each of the test regions 8a, 8b is in accordance with the example explained with reference to FIG. 15, for example. Each of the doped test regions 8a, 8b is connected to a respective contact pad 61a-66a, 61b-66b. The contact pads 61a-66a, 61b-66b are arranged in series in the first direction x1 and between the two alignment pads 71, 72. The doped test regions 8a, 8b are arranged in different epitaxial layers 221a, 221b.

In the example illustrated in FIG. 17, contact pads 61a, 66a may be used to drive a current through the first doped test region 8a, and contact pads 61b, 66b may be used to drive a current through the second doped test region 8b.

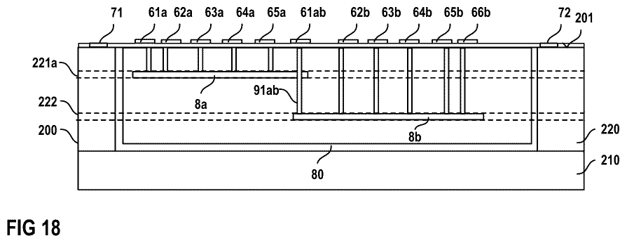

FIG. 18 shows a modification of the test structure illustrated in FIG. 17. In the example illustrated in FIG. 18, contact pad 61ab is connected to both of the test regions 8a, 8b through a respective contact region 91ab. Contact pad 61ab, together with contact pad 61a, may be used to drive a current through the first test region 8a in a first measurement sequence and, together with contact pad 66b, may be used to drive a current through the second test region 8b in a second measurement sequence.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A test structure, comprising:
a pad arrangement arranged above a kerf region of a semiconductor wafer,
wherein the pad arrangement comprises:
contact pads arranged in series in a first direction; and
two alignment pads arranged in series with the contact pads in the first direction such that the contact pads are arranged between the two alignment pads,
wherein each of the contact pads comprises a metal, and
wherein each of the alignment pads is different from each of the contact pads and is configured to be irreversibly deformed when coming into contact with a probe needle.

2. The test structure of claim 1, wherein the metal comprises one of tungsten and titanium.

3. The test structure of claim 1, wherein each of the alignment pads comprises a plurality of elements that are spaced apart from each other and are configured to break off when coming into contact with a probe needle.

4. The test structure of claim 3, wherein the elements comprise an oxide.

5. The test structure of claim 3, wherein the elements are separated from each other by trenches extending from a surface of an insulating layer into the insulating layer.

6. The test structure of claim 5, wherein the contact pads are formed above the surface of the insulating layer.

7. The test structure of claim 6, wherein the trenches extend to a surface of the kerf region.

8. The test structure of claim 6, wherein each of the alignment pads is formed above an insulating trench extending from a surface of the kerf region into the kerf region and filled with an insulating layer, and wherein bottoms of the trenches separating the needles are spaced apart from a bottom of the insulating trench.

9. The test structure of claim 3, wherein the elements have the shape of needles.

10. The test structure of claim 1, further comprising:
a doped test region in the kerf region of the semiconductor wafer and connected to the contact pads.

11. The test structure of claim 10, wherein the doped test region is connected to the contact pads through doped contact regions arranged in the kerf region and electrically conducting vias arranged in an insulating layer formed on top of the semiconductor wafer.

12. The test structure of claim 10, wherein the doped test region comprises at least one of:
a first region of a first doping type;
a second region comprising a plurality of elongated doped regions of the first doping type and spaced apart from each other in a direction perpendicular to longitudinal directions of the doped regions; and
a third region comprising a plurality of elongated first doped regions of the first doping type and a plurality of elongated second doped regions of a second doping type complementary to the first doping type, wherein the first and second doped regions are arranged alternatingly in a direction perpendicular to longitudinal directions of the first and second doped regions.

13. The test structure of claim 12, wherein the doped test region comprises each of the first region, the second region, and the third region, and wherein the first region, the second region, and the third region are arranged next to each other in a direction corresponding to longitudinal directions of the doped regions of the second region and the first and second doped regions of the third region.

14. The test structure of claim 12, wherein the doped test region is arranged in an epitaxial layer of the semiconductor wafer.

15. The test structure of claim 14, wherein the doped test region is a first doped test region and the epitaxial layer is a first epitaxial layer, and wherein the test structure further comprises at least one second doped test region arranged in a second epitaxial layer different from the first epitaxial layer.

16. The test structure of claim 15, wherein contact pads connected to the first doped test region and the second doped test region are arranged in series in the first direction and are arranged between the two alignment pads.

17. The test structure of claim 12, further comprising:
a doped shielding region of the second doping type that surrounds the doped test region in the kerf region of the semiconductor wafer.
